(19) United States
(12) Patent Application Publication
(10) Pub. No.: US 2026/0301977 A1
(43) Pub. Date: Oct. 1, 2026

(54) USE OF OXIDATION RESISTANT COATINGS TO INCREASE THIN WALLED CLADDING TENSILE STRENGTH TO INCREASE URANIUM LOADINGS

(71) Applicant: Westinghouse Electric Company LLC, Cranberry Township, PA (US)

(72) Inventor: Edward J. LAHODA, Edgewood, PA (US)

(73) Assignee: Westinghouse Electric Company LLC, Cranberry Township, PA (US)

(21) Appl. No.: 19/705,456

(22) Filed: Jun. 11, 2026

Related U.S. Application Data
(62) Division of application No. 18/051,925, filed on Nov. 2, 2022, now abandoned.

(51) Int. Cl. G21C 3/07; G21C 21/02

(52) U.S. Cl. CPC G21C 3/07; G21C 21/02

(57) ABSTRACT

A cladding for housing enriched nuclear fuel in a nuclear fuel assembly is provided. The cladding comprises a base layer comprised of Zirconium alloy and a coating for the base layer. The base layer has a wall thickness of less than 1 millimeter. The coating comprises a primary layer comprised of Chromium or a Chromium alloy. The primary layer has a thickness in the range of about 5 to about 50 microns. A fuel rod for a nuclear reactor core and a method for producing a fuel rod are also provided.

### CROSS-REFERENCE TO RELATED APPLICATIONS

This application is a divisional application claiming priority under 35 U.S.C. § 120 to U.S. Patent Application Serial No. 18/051,925, filed Nov. 2, 2022, the entire disclosure of which is hereby incorporated by reference herein.

### GOVERNMENT SUPPORT

This invention was made with government support under Government Contract No. DE-NE00009033 awarded by the Department of Energy. The government has certain rights in the invention.

### BACKGROUND

Zirconium alloy is widely adopted as a standard cladding material in nuclear fuel rods. However, current Nuclear Regulatory Commission licensed fuel assembly and cladding designs limit the loading capacity of nuclear fuel within a given fuel rod of a fuel assembly, thereby limiting the obtainable fuel burnup, generating an excessive number of spent nuclear fuel elements, and/or increasing the downtime required for refueling. Implementing design changes by changing the dimensions of the fuel cladding used in the fuel assemblies and/or nuclear fuel loaded therein are cost prohibitive for fuel assembly manufacturers and/or energy suppliers. Therefore, a need exists to develop alternative cladding designs and manufacturing methods thereof to optimize the cost and performance of nuclear fuel rods while maintaining the current dimensions of the fuel rods.

### SUMMARY

The following summary is provided to facilitate an understanding of some of the innovative features unique to the aspects disclosed herein and is not intended to be a full description. A full appreciation of the various aspects disclosed herein can be gained by taking the entire specification, claims, and abstract as a whole.

In various aspects, a cladding for housing enriched nuclear fuel in a nuclear fuel assembly is disclosed. In some aspects, the cladding includes a base layer comprised of Zirconium alloy and a coating for the base layer. In some aspects, the base layer has a wall thickness of less than 1 millimeter. In some aspects, the coating includes a primary layer. In some aspects, the primary layer is comprised of Chromium or a Chromium alloy and has a thickness in the range of about 5 to about 50 microns.

In various aspects, a fuel rod for a nuclear reactor core is disclosed. In some aspects, the fuel rod includes a strengthened cladding and an amount of nuclear fuel comprised of an Uranium containing compound. In some aspects, the strengthened cladding includes a base layer comprised of Zirconium alloy, and a coating for the base layer. In some aspects, the base layer has a wall thickness in the range of about 0.2 millimeters to about 0.6 millimeters and defines a cavity therein. In some aspects, the coating includes a primary layer, wherein the primary layer is comprised of Chromium or a Chromium alloy and wherein the primary layer has a thickness in the range of about 5 to about 50 microns. In some aspects, the amount of nuclear fuel is loaded into the cavity of the base layer of the strengthened cladding and can support an 18 month fuel cycle at a burnup of about 68 Megawatt-days/kilogram-Uranium or more. In some aspects, the Uranium containing compound is enriched to a level of about 5% Uranium-235 (“²³⁵U”) or less.

In various aspects, a method for producing a fuel rod for a nuclear reactor is disclosed. In some aspects, the method includes producing a base layer for a cladding of the fuel rod, applying a coating onto the base layer to produce the cladding, and loading the cladding with an amount of Uranium based fuel. In some aspects, the base layer is comprised of a Zirconium alloy, has a wall thickness of less than 1 millimeter, and defines a cavity therein. In some aspects, the coating includes a primary layer comprised of Chromium or a Chromium alloy, wherein the primary layer has a thickness in the range of about 5 to about 50 microns. In some aspects, the Uranium based fuel is enriched to a level of about 4.95% ²³⁵U or less; and the amount of nuclear fuel can support an 18 month fuel cycle at a burnup of about 68 Megawatt-days/kilogram-Uranium or more.

These and other objects, features, and characteristics of the present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of any of the aspects disclosed herein.

### BRIEF DESCRIPTION OF THE DRAWINGS

The various aspects described herein, together with objects and advantages thereof, may best be understood by reference to the following description, taken in conjunction with the accompanying drawings as follows.

FIG. 1 illustrates a cross-sectional elevation view of a fuel assembly, according to at least one non-limiting aspect of the present disclosure.

FIG. 2 illustrates a cross-sectional view of a fuel rod, according to at least one non-limiting aspect of the present disclosure.

FIG. 3 is a cross-sectional schematic representation of a cladding, in accordance with at least one non-limiting aspect of the present disclosure.

FIG. 4 is a cross-sectional schematic representation of a coating, in accordance with at least one non-limiting aspect of the present disclosure.

FIG. 5 is a cross-sectional schematic representation of a coating, in accordance with at least one non-limiting aspect of the present disclosure.

FIG. 6 is a cross-sectional schematic representation of a coating, in accordance with at least one non-limiting aspect of the present disclosure.

FIG. 7 is a cross-sectional schematic representation of a fuel rod, in accordance with at least one non-limiting aspect of the present disclosure.

Corresponding reference characters indicate corresponding parts throughout the several views. The exemplifications set out herein illustrate various aspects of the present disclosure, in one form, and such exemplifications are not to be construed as limiting the scope of any of the aspects disclosed herein.

### DETAILED DESCRIPTION

Certain exemplary aspects of the present disclosure will now be described to provide an overall understanding of the principles of the composition, function, manufacture, and use of the compositions and methods disclosed herein. An example or examples of these aspects are illustrated in the accompanying drawing. Those of ordinary skill in the art will understand that the compositions, articles, and methods specifically described herein and illustrated in the accompanying drawing are non-limiting exemplary aspects and that the scope of the various examples of the present disclosure is defined solely by the claims. The features illustrated or described in connection with one exemplary aspect may be combined with the features of other aspects. Such modifications and variations are intended to be included within the scope of the present disclosure.

Reference throughout the specification to “various examples,” “some examples,” “one example,” “an example,” or the like, means that a particular feature, structure, or characteristic described in connection with the example is included in an example. Thus, appearances of the phrases “in various examples,” “in some examples,” “in one example,” “in an example,” or the like, in places throughout the specification are not necessarily all referring to the same example. Furthermore, the particular features, structures, or characteristics may be combined in any suitable manner in an example or examples. Thus, the particular features, structures, or characteristics illustrated or described in connection with one example may be combined, in whole or in part, with the features, structures, or characteristics of another example or other examples without limitation. Such modifications and variations are intended to be included within the scope of the present examples.

In the following description, like reference characters designate like or corresponding parts throughout the several views of the drawings. Also in the following description, it is to be understood that such terms as “forward,” “rearward,” “left,” “right,” “above,” “below,” “upwardly,” “downwardly,” and the like are words of convenience and are not to be construed as limiting terms.

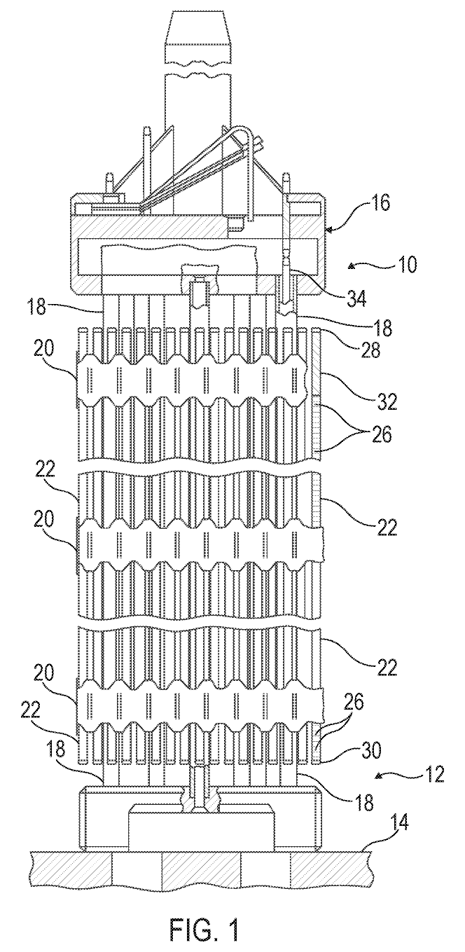

In a typical nuclear reactor, such as a pressurized water reactor (“PWR”), heavy water reactor (e.g., a CANDU), or a boiling water reactor (“BWR”), the reactor core can include a large number of fuel assemblies, each of which includes a plurality of elongated fuel elements or fuel rods. For example, FIG. 1 illustrates a cross-sectional elevation view of a fuel assembly 10, according to at least one non-limiting aspect of this disclosure. The fuel assembly 10 includes an organized array of elongated fuel rods 22. The fuel rods 22 can house a plurality of fuel pellets 26 each comprising a fissile material capable of creating the reactive power of the reactor through fission reactions.

The fuel rods 22 may be supported by one or more transverse grids 20 which attach to guide thimbles 18. The guide thimbles 18 extend longitudinally between top nozzle 16 and bottom nozzle 12 and are configured for control rods 34 to operably move therethrough. Opposite ends of the guide thimbles 18 can attach to the top nozzle 16 and bottom nozzle 12, respectively. The bottom nozzle 12 can be configured to support the fuel assembly 10 on a reactor vessel lower core plate 14 in the core region of a reactor (not shown). A liquid coolant such as water, or water including a neutron absorbing material such as boron, may be pumped to the fuel assembly 10 upwardly through a plurality of flow openings in the lower core plate 14. The bottom nozzle 12 of the fuel assembly 10 may pass the coolant flow to and along the fuel rods 22 of the assembly 10 in order to extract heat generated as a result of the fission reactions occurring therein.

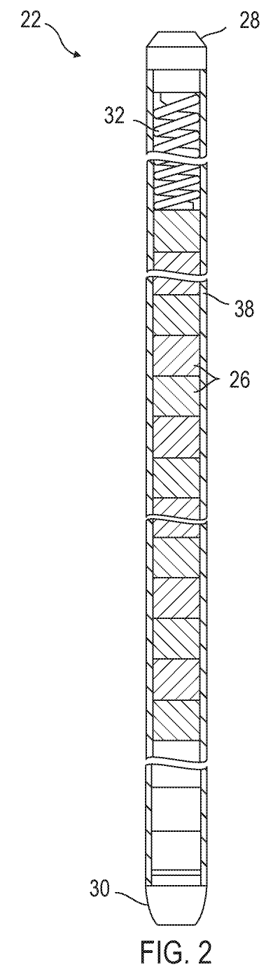

FIG. 2 illustrates an enlarged cross-sectional view of a fuel rod 22, according to at least one non-limiting aspect of this disclosure. Referring now to FIGS. 1-2, as mentioned above, each of the fuel rods 22 may include a plurality of nuclear fuel pellets 26. The fuel pellets 26 are housed within an elongated cladding 38 tube that is closed at opposite ends by an upper end plug 28 and a lower end plug 30. The pellets 26 may be maintained in a stack by a plenum spring 32 disposed between the upper end plug 28 and the top of the pellet stack. However, in other aspects, the pellets 26 may be otherwise configured via alternate mechanisms. In addition to housing nuclear fuel, claddings provide a medium for transferring heat from fissile fuel into coolant surrounding the fuel rods.

Claddings typically employ materials having a low neutronic penalty and corrosion resistance in various reactor environment conditions. For example, Zirconium (“Zr”) alloy has been adopted as a standard material for claddings typically employed in nuclear fuel assemblies for PWRs. Under low temperature reactor operating conditions, such as, for example, at temperatures of about 375°C or less, a Zr-alloy cladding can be exposed to coolant without compromising cladding properties such as, for example, structural integrity and/or overall heat transfer characteristics. However, Zr-alloy based claddings may require protective surface treatments depending on reactor environments and/or operating conditions.

Accident Tolerant Fuel (“ATF”) has been developed in an effort to enhance the protection of nuclear fuel under unexpectedly high operating temperatures and/or accident conditions. For example, Chromium (hereinafter referred to as “Cr”) coatings are compatible with PWR and/or CANDU reactor chemistries and accident environments, and are fairly inexpensive to apply onto Zr-alloys. Thus, Cr coatings can be deposited onto a Zr alloy cladding to provide a relatively inexpensive ATF for PWR reactors. The deposition of the Cr coating can decrease the oxidation rate of the cladding surface at Beyond Design Basis Accident (“BDBA”) temperatures, such as, for example, temperatures greater than 1200 °C. However, while Cr is very compatible with reactor environments of PWR type reactors, Cr is not compatible with normal operation BWR chemistry. BWRs employ other Cr based alloys or compounds such as CrN or CrNbN. Furthermore, although ATFs employ relatively thin coatings having thicknesses of less than about 100 microns, the increased thickness of the claddings and/or coatings can still suffer from a substantial net neutronic penalty, thereby compromising nuclear fuel efficiency and/or burnup.

In practice, technological developments in the nuclear energy sector can be difficult to implement. For example, in order to make any design changes regarding the overall dimensions of a fuel assembly, the fuel rod, the characteristics of the nuclear fuel, and/or licensing regulations require significant investments of time and money to be made by manufacturers and/or suppliers prior to obtaining approval to make and/or use the new design. Thus, manufacturers typically employ claddings for having standard dimensions, such as, for example, an outer diameter of about 9.5 millimeters, when manufacturing nuclear fuel rods in order to comply with any pre-existing design-basis requirements, thereby avoiding any unnecessary expenses.

Additionally, since a cladding must comply with regulated strength and/or safety requirements, conventional claddings are typically supplied with a standard wall thickness to provide a predictable safety margin. For example, the design basis for some Zr-alloy based claddings calls for a wall thickness of 0.575 millimeters. Accordingly, some claddings are manufactured to a minimum thickness of 0.575 millimeters to provide sufficient structural integrity for normal reactor operation. As a result, the volumetric capacity, and thus, the fuel capacity, is limited in a standard cladding. Although the volumetric capacity limitations of fissile fuel in current claddings can be offset with ²³⁵U enrichment of Uranium-based fuels past levels of about 5%, the upper ²³⁵U enrichment level of Uranium-based fuel in LWRs is currently regulated at 4.95%. Moreover, all facilities that handle commercial nuclear fuel, such as, for example, facilities associated with fuel fabrication, fuel transportation, and nuclear power plants, are built, licensed and operated to this requirement. Thus, the limited capacity for fissile material in currently available claddings for use in LWRs can increase the frequency of refueling and/or amount of fresh fuel rods required to refuel for maintaining a given power output.

Various methods and devices provided by the present disclosure optimize the technical and economic aspects of providing fuel rods for fuel assemblies in nuclear reactors such as, for example, LWR type reactors. In some implementations, the optimization can increase nuclear fuel capacity and fuel burnup in a given reactor core using existing fuel technology without enlarging the overall footprint of the fuel rod and/or compromising the structural integrity of the cladding therein. Accordingly, various aspects of the present disclosure provide various methods and devices for maximizing the performance of nuclear fuel in existing LWR designs thereby maintaining adherence to nuclear energy regulations without requiring costly design revision approvals.

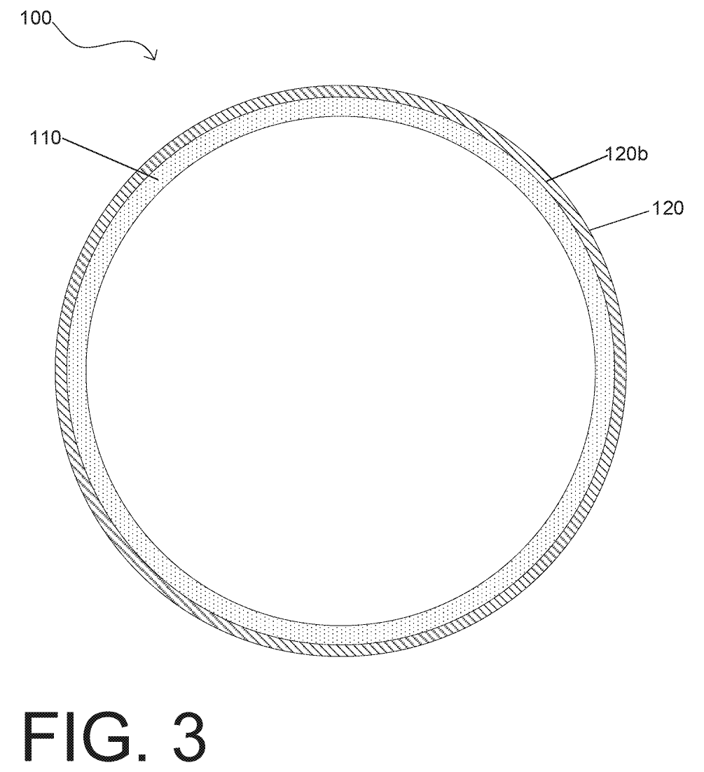

Referring to FIG. 3, a cross-sectional schematic representation of a cladding 100 for housing enriched nuclear fuel in a nuclear fuel assembly is provided, in accordance with at least one non-limiting aspect of the present disclosure. In various examples, the cladding 100 includes a base layer 110 comprised of a Zr-alloy and a coating 120 for the base layer 110. The coating 120 includes a primary layer 120b comprised of Cr or an alloy thereof.

In various examples, the base layer 110 has a wall thickness of less than 1 millimeter. In some examples, the base layer 110 can have a wall thickness in the range of about 0.2 millimeters to about 0.575 millimeters, or to about 0.5 millimeters, or to about 0.475 millimeters. In one example, the base layer 110 has a wall thickness of about 0.456 millimeters.

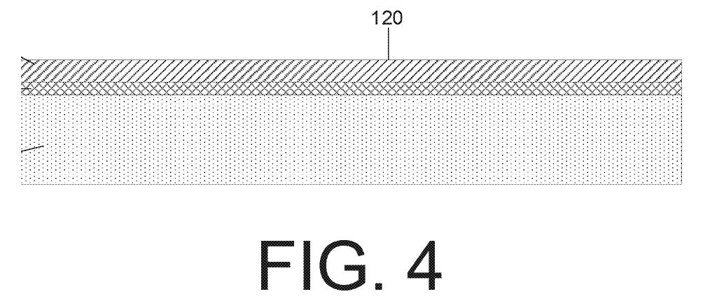

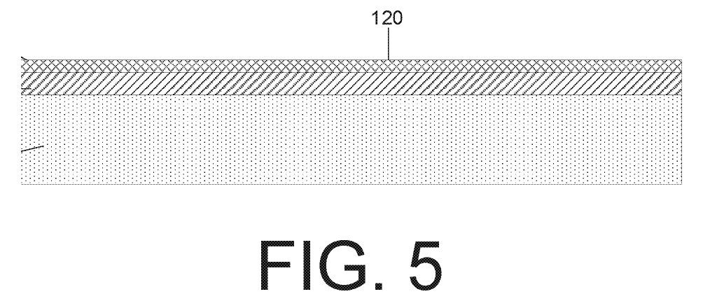

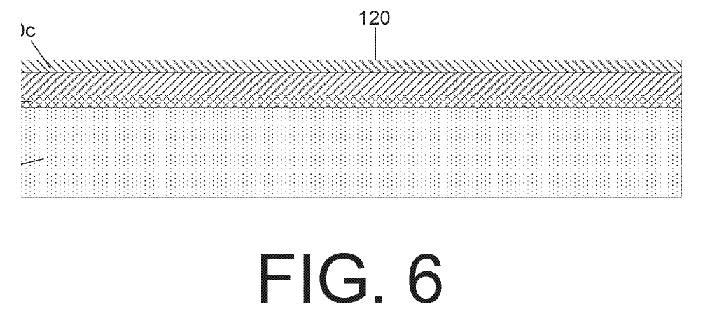

In certain examples of the cladding 100, the coating 120 can be configured to include one or more layers surrounding and/or underlying the primary layer 120b. For example, FIGS. 4-6 illustrate various multilayer configurations of the coating 120 deposited onto a base layer 110. FIG. 4 depicts a coating 120 including an interlayer 120a positioned between the base layer 110 and the primary layer 120b and FIG. 5 depicts a coating 120 including a top layer 120c surrounding the primary layer 120b. FIG. 6 depicts a coating 120 including layers 120a, 120b and 120c. In examples of the cladding 100 including a multilayer configuration of the coating 120, the interlayer 120a and/or the top layer 120c can each be independently configured to have a thickness of about 10 microns or less.

Now referring to FIGS. 3-6, the primary layer 120b can have a thickness in the range of about 5 to about 50 microns. In some examples, the primary layer 120b can be comprised of a Cr-alloy including at least one of Yttrium, Molybdenum, Iron, Aluminum, or Nitrogen. The primary layer 120b can be configured to impart a tensile strength thereof onto an underlying layer without significantly increasing the neutronic penalty of the coating 120. For example, in the multilayer configuration of the coating 120, the thickness of the primary layer 120b can be configured to have a lower thickness than a primary layer 120b of a single layer coating 120. In certain examples, the primary layer 120b has a thickness in the range of about 5 microns to about 20 microns.

Now referring to FIGS. 4 and 6, in examples of the coating 120 including an interlayer 120a, the interlayer 120a can be comprised of a material having a eutectic formation temperature with Zr and/or Cr greater than 1500°C or greater than 1600 °C, or greater than 2000 °C, or greater than a BDBA temperature. For example, the interlayer 120a can be comprised of Molybdenum, Tantalum, or Niobium. Currently available Zr-alloy based claddings incorporating a Cr-Zr interface can begin to form Cr-Zr eutectics at a relatively low temperature of about 1333 °C. Thus, an interlayer 120a incorporating this configuration can maintain a barrier between the Zr-alloy of the base layer 110 and the Cr-based primary layer 120b at relatively high temperatures, such as, for example, temperatures greater than 1500°C. Accordingly, a cladding 100 can be configured with an interlayer 120a to inhibit a formation of a low melting Cr-Zr eutectic material, thereby further increasing the ballooning and/or bursting resistance of the cladding 100 at relatively high transient and/or accident condition temperatures.

Now referring to FIGS. 5-6, the top layer 120c can be configured to provide the enhanced protection of an ATF in BDBA, high temperature, and/or normal operating conditions. For example, the top layer 120c can be comprised of a Cr-alloy or a ceramic material. In some examples, the top layer 120c can be comprised of a Cr-alloy including at least one of Yttrium, Molybdenum, Iron or Aluminum. In certain examples, the top layer 120c is configured as a Cr-alloy including Yttrium or Molybdenum or a Chromium alloy including Iron and/or Aluminum. In examples where the top layer 120c is comprised of a ceramic material, the top layer 120c can include Chromium, Nitrogen, Niobium, or any combination thereof. These alloys and ceramics are known to tolerate coolant having an O₂ content, such as, for example, up to about 10 ppm O₂. Thus, a cladding 100 including a top layer 120c can be configured to provide protection from excessive corrosion in a BWR application.

The cladding 100 as described hereinabove can be configured to provide an optimized storage capacity therein without increasing the overall footprint of the cladding within a nuclear reactor. For example, the outer diameter of the cladding 100 can be configured to be about the same as, or slightly less than, the outer diameter of a conventional cladding. In some examples, the cladding 100 is configured with an outer diameter of about 9.5 millimeters or less. In certain examples, the cladding 100 has an outer diameter of about 9.5 millimeters and includes a base layer having a wall thickness of less than 0.575 millimeters. In one example, the cladding 100 has an outer diameter of about 9.5 millimeters and includes a base layer having a wall thickness of about 0.46 millimeters. A cladding 100 incorporating this configuration can provide about a 6% increase in volumetric loading capacity therein and a decrease in neutronic penalty compared to currently available claddings having a wall thickness of 0.575 millimeters, without increasing the outer surface area and/or overall footprint of the cladding. Thus, the cladding 100 can be configured to store a greater volume of fuel without requiring a redesign of the reactor enclosure and/or the coolant flow path therein, thereby avoiding cost-prohibitive design changes.

Moreover, the inventor of the present disclosure has determined that the strength and/or blowout resistance of a base layer 110 can be reinforced with a primary layer 120b having an unexpectedly low thickness. For example, the inventor of the present disclosure has carried out blowout testing of Zr-alloy claddings wherein the claddings incorporating Cr-based coatings having a thickness of about 10-20 microns provided an increase of about 16% over uncoated claddings. Thus, the cladding 100 including a relatively thin-walled base layer 110 as described hereinabove can be configured with a coating 120 to provide an increased amount of fuel storage over currently available claddings without compromising the blowout resistance thereof.

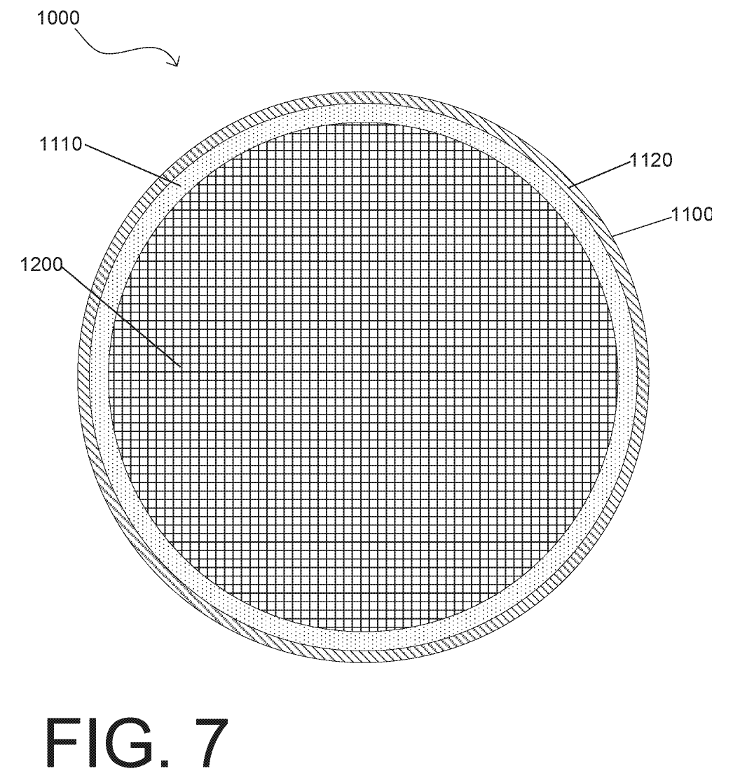

Now referring to FIG. 7, a cross-sectional schematic representation of a fuel rod 1000 for a nuclear reactor core including a strengthened cladding 1100 and nuclear fuel 1200 is provided, in accordance with at least one non-limiting aspect of the present disclosure. In various examples, the fuel rod 1000 includes a strengthened cladding 1100 and an amount of nuclear fuel 1200. In certain examples, the strengthened cladding 1100 is configured with an outer diameter of about 9.5 millimeters or less. The amount of nuclear fuel 1200 is comprised of Uranium enriched to a level of less than about 5%, or less than about 4%, or less than about 3%. For example, about 4.95% of the Uranium content of the amount of nuclear fuel 1200 can be comprised of ²³⁵U. The amount of nuclear fuel 1200 can be configured as a number of fuel pellets. For example, the amount of nuclear fuel 1200 can include a number of standard Uranium Dioxide based fuel pellets or a number of high density fuel pellets, such as, for example, fuel pellets having an enriched Uranium density of about 2% or more than in standard fuel pellets.

Still referring to FIG. 7, the strengthened cladding 1100 includes a base layer 1110 comprised of Zr-alloy and a coating 1120 comprising a primary layer, and is similar in many respects to other claddings disclosed elsewhere in the present disclosure, which are not repeated herein at the same level of detail for brevity. In various examples, the base layer 1110 defines a cavity therein and has a wall thickness in the range of about 0.2 millimeters to about 0.575 millimeters. The primary layer of the coating 1120 has a thickness in the range of about 5 microns to about 50 microns and is comprised of Chromium or a Cr-alloy. The amount of nuclear fuel 1200 of the fuel rod 1000 is loaded into the cavity of the base layer 1110. In examples where the primary layer of the coating 1120 is comprised of a Cr-alloy, the Cr-alloy can include at least one of Yttrium, Molybdenum, Iron, Aluminum, or Nitrogen. In some examples, the coating 1120 comprises multiple layers.

The base layer 1110 and the coating 1120 can be independently configured similarly to the base layer 110 and the coating 120, respectively, as described hereinabove. Thus, the thicknesses of the base layer 1110 and the coating 1120 can be configured to provide an increased storage capacity over currently available claddings without compromising the blowout resistance thereof and/or requiring a larger footprint, thereby avoiding costly revisions to existing nuclear reactor vessel designs and/or coolant flow conduits therein.

A strengthened cladding 1100 incorporating a high capacity configuration as described hereinabove can optimize the useful lifetime of a fuel rod 1000. For example, a strengthened cladding 1100 incorporating a base layer 1110 having a wall thickness of about 0.456 millimeters can provide an increase in volumetric capacity of about 6 % over currently available claddings having a wall thickness of about 0.575 millimeters. When this high capacity configuration of the strengthened cladding 1100 is loaded with an amount of nuclear fuel 1200 configured as high density fuel pellets comprised of Uranium enriched to a level of about 4.95%, the resulting fuel rod 1000 can perform at a level comparable to a standard wall thickness cladding loaded with fuel enriched to about 5.34%, thereby providing a burnup of about 68 megawatt-days/kilogram-Uranium (“MWd/kg-U”) in an 18 month utility cycle. Accordingly, the fuel rod 1000 can be configured to provide a fuel burnup associated with fuel enrichment levels of greater than 5% without exceeding the upper enrichment limit of 4.95%.

As discussed herein, a method for producing a fuel rod is provided by the present disclosure. In various examples, the method includes producing a base layer for a cladding of the fuel rod, applying a coating onto the base layer to produce the cladding and loading the cladding with an amount of Uranium based fuel enriched to a level of about 4.95% or less to produce the fuel rod. The base layer has a wall thickness of less than 1 millimeter, defines a cavity therein, and is comprised of a Zirconium alloy. The coating can include a primary layer comprised of Chromium or a Chromium alloy and can have a thickness in the range of about 5 to about 50 microns.

In some examples, the method can include applying a multilayer coating onto the base layer. For example, the method can include applying an interlayer onto the base layer before applying the primary layer and/or applying a top layer onto the primary layer. Each of the interlayer and the top layer is similar in many respects to other interlayers and top layers, respectively, described elsewhere in the present disclosure. Thus the interlayer can be configured to increase a formation temperature of a eutectic between the base layer and the primary layer. Additionally, the top layer can be configured to protect underlying layers from corrosion resistance in a BWR application. Accordingly, the method can be configured to further enhance the fuel rod’s resistance to ballooning, bursting, and/or oxidation at temperatures associated with accident conditions and/or transient events.

The method can be configured to incorporate various deposition and/or application processes. For example, the primary layer of the coating can applied with a cold spray process, a thermal spray process, or a Physical Vapor Deposition process, such as, for example, Cathodic Arc deposition, Magnetron Sputtering, or Pulse Laser deposition. In examples where the method includes applying an interlayer and/or a top layer, the interlayer and/or top layer can be applied with a thermal spray process or a Physical Vapor Deposition process.

The fuel rod is similar in many respects to other fuel rods described elsewhere in the present disclosure. Thus, the fuel rod can be configured with a high capacity strengthened cladding to provide an optimized fuel storage capacity without compromising structural integrity and/or surface properties at high temperatures, thereby providing a fuel burnup associated with fuel enrichment levels of greater than 5% without exceeding the upper enrichment limit of 4.95%. In various examples, the method includes loading the cladding with an amount of nuclear fuel to support an 18 month fuel cycle at a burnup of about 68 Megawatt-days/kilogram-Uranium or more. Accordingly, a method incorporating this configuration can provide a fuel rod having increased burnup without utilizing increased enrichment levels and/or requiring redesigns of reactor vessel internals. Accordingly, the method can optimize the performance of nuclear fuel in a fuel rod without compromising compatibility with current reactor vessels and/or requiring costly modifications in the designs thereof.

Various aspects of the present disclosure include, but are not limited to, the aspects listed in the following numbered clauses.

Clause 1 - A cladding for housing enriched nuclear fuel in a nuclear fuel assembly, the cladding comprising a base layer and a coating for the base layer. The base layer is comprised of Zirconium alloy and has a wall thickness of less than 1 millimeter. The coating comprises a primary layer. The primary layer is comprised of Chromium or a Chromium alloy, and has a thickness in the range of about 5 to about 50 microns.

Clause 2 - The cladding of clause 1, wherein the base layer has a wall thickness in the range of about 0.2 millimeters to about 0.6 millimeters.

Clause 3 - The cladding of any one of clauses 1-2, wherein the Chromium alloy comprises Yttrium, Molybdenum, Iron, Aluminum, Nitrogen, or a combination thereof.

Clause 4 - The cladding of any one of clauses 1-3, wherein the coating further comprises an interlayer. The interlayer is positioned between the base layer and the primary layer, and is configured to increase a formation temperature of a eutectic between the base layer and the primary layer.

Clause 5 - The cladding of clause 4, wherein the interlayer is comprised of Molybdenum, Tantalum, or Niobium.

Clause 6 - The cladding of any one of clauses 4-5, wherein the interlayer has a thickness in the range of about 10 microns or less.

Clause 7 - The cladding of any one of clauses 1-6, wherein the coating further comprises a top layer surrounding the primary layer. The top layer is comprised of a Chromium alloy or a ceramic material.

Clause 8 - The cladding of clause 7, wherein the Chromium alloy comprises Yttrium or Molybdenum.

Clause 9 - The cladding of clause 7, wherein the Chromium alloy comprises Iron and Aluminum.

Clause 10 - The cladding of clause 7, wherein the ceramic material comprises Chromium, Nitrogen, Niobium, or any combination thereof.

Clause 11 - The cladding of any one of clauses 7-10, wherein the top layer has a thickness of about 10 microns or less.

Clause 12 - The cladding of any one of clauses 1-11, wherein the base layer has a wall thickness of less than 0.575 millimeters.

Clause 13 - The cladding of clause 12, wherein the base layer has a wall thickness of about 0.5 millimeters or less.

Clause 14 - A fuel rod for a nuclear reactor core, the fuel rod comprising a strengthened cladding and an amount of nuclear fuel comprised of Uranium. The strengthened cladding comprises a base layer comprised of Zirconium alloy, and a coating for the base layer. The base layer has a wall thickness in the range of about 0.2 millimeters to about 1 millimeter and defines a cavity therein. The coating comprises a primary layer. The primary layer is comprised of Chromium or a Chromium alloy, and has a thickness in the range of about 5 to about 50 microns. The amount of nuclear fuel is loaded into the cavity of the base layer of the strengthened cladding, and can support an 18 month fuel cycle at a burnup of about 68 Megawatt-days/kilogram-Uranium or more. The Uranium is enriched to a level of about 5% or less.

Clause 15 - The fuel rod of clause 14, wherein the Chromium alloy of the primary layer comprises Yttrium, Molybdenum, Iron, Aluminum, Nitrogen, or a combination thereof.

Clause 16 - The fuel rod of any one of clauses 14-15, wherein the base layer has a wall thickness in the range of about 0.2 millimeters to about 0.5 millimeters.

Clause 17 - A method for producing a fuel rod for a nuclear reactor, the method comprising producing a base layer for a cladding of the fuel rod, applying a coating onto the base layer to produce the cladding, and loading the cladding with an amount of Uranium based fuel. The base layer is comprised of a Zirconium alloy, has a wall thickness of less than 1 millimeter, and defines a cavity therein. The coating comprises a primary layer having a thickness in the range of about 5 to about 50 microns, wherein the primary layer is comprised of Chromium or a Chromium alloy. The Uranium based fuel is enriched to a level of about 4.95% or less, and the amount of Uranium based fuel can support an 18 month fuel cycle at a burnup of about 68 Megawatt-days/kilogram-Uranium or more.

Clause 18 - The method of clause 17, wherein the primary layer of the coating is applied with a cold spray, a thermal spray, or a Physical Vapor Deposition process.

Clause 19 - The method of any one of clauses 17-18, wherein the coating further comprises an interlayer configured to increase a formation temperature of a eutectic between the base layer and the primary layer. The interlayer is applied with a thermal spray process or a Physical Vapor Deposition process before applying the primary layer.

Clause 20 - The method of any one of clauses 17-19, wherein the coating further comprises a top layer. The top layer is comprised of a Chromium alloy or a ceramic material. The top layer is applied with a thermal spray process or a Physical Vapor Deposition process after applying the primary layer.

Various features and characteristics are described in this specification to provide an understanding of the composition, structure, production, function, and/or operation of the disclosure, which includes the disclosed methods and systems. It is understood that the various features and characteristics of the disclosure described in this specification can be combined in any suitable manner, regardless of whether such features and characteristics are expressly described in combination in this specification. The Inventors and the Applicant expressly intend such combinations of features and characteristics to be included within the scope of the disclosure described in this specification. As such, the claims can be amended to recite, in any combination, any features and characteristics expressly or inherently described in, or otherwise expressly or inherently supported by, this specification. Furthermore, the Applicant reserves the right to amend the claims to affirmatively disclaim features and characteristics that may be present in the prior art, even if those features and characteristics are not expressly described in this specification. Therefore, any such amendments will not add new matter to the specification or claims and will comply with the written description, sufficiency of description, and added matter requirements.

With respect to the appended claims, those skilled in the art will appreciate that recited operations therein may generally be performed in any order. Also, although various operational flows are presented in a sequence(s), it should be understood that the various operations may be performed in other orders than those that are illustrated or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

The invention(s) described in this specification can comprise, consist of, or consist essentially of the various features and characteristics described in this specification. The terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. Thus, a method or system that “comprises,” “has,” “includes,” or “contains” a feature or features and/or characteristics possesses the feature or those features and/or characteristics but is not limited to possessing only the feature or those features and/or characteristics. Likewise, an element of a composition, coating, or process that “comprises,” “has,” “includes,” or “contains” the feature or features and/or characteristics possesses the feature or those features and/or characteristics but is not limited to possessing only the feature or those features and/or characteristics and may possess additional features and/or characteristics.

The grammatical articles “a,” “an,” and “the,” as used in this specification, including the claims, are intended to include “at least one” or “one or more” unless otherwise indicated. Thus, the articles are used in this specification to refer to one or more than one (i.e., to “at least one”) of the grammatical objects of the article. By way of example, “a component” means one or more components and, thus, possibly more than one component is contemplated and can be employed or used in an implementation of the described compositions, coatings, and processes. Nevertheless, it is understood that use of the terms “at least one” or “one or more” in some instances, but not others, will not result in any interpretation where failure to use the terms limits objects of the grammatical articles “a,” “an,” and “the” to just one. Further, the use of a singular noun includes the plural, and the use of a plural noun includes the singular, unless the context of the usage requires otherwise.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 10” includes all sub-ranges between (and including) the recited minimum value of 1 and the recited maximum value of 10, that is, having a minimum value equal to or greater than 1 and a maximum value equal to or less than 10. Also, all ranges recited herein are inclusive of the end points of the recited ranges. For example, a range of “1 to 10” includes the end points 1 and 10. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

As used in this specification, particularly in connection with layers, the terms “on,” “onto,” “over,” and variants thereof (e.g., “applied over,” “formed over,” “deposited over,” “provided over,” “located over,” and the like) mean applied, formed, deposited, provided, or otherwise located over a surface of a substrate but not necessarily in contact with the surface of the substrate. For example, a layer “applied over” a substrate does not preclude the presence of another layer or other layers of the same or different composition located between the applied layer and the substrate. Likewise, a second layer “applied over” a first layer does not preclude the presence of another layer or other layers of the same or different composition located between the applied second layer and the applied first layer.

Whereas particular examples of this disclosure have been described above for purposes of illustration, it will be evident to those skilled in the art that numerous variations of the details of the present disclosure may be made without departing from the disclosure as defined in the appended claims.

What is claimed is:

1. A fuel rod for a nuclear reactor core, the fuel rod comprising:
a strengthened cladding, the strengthened cladding comprising:
a base layer comprised of Zirconium alloy, wherein the base layer has a wall thickness in a range of 0.2 millimeters to 1 millimeter, and wherein the base layer defines a cavity therein; and
a coating for the base layer, the coating comprising a primary layer, wherein the primary layer is comprised of Chromium or a Chromium alloy, wherein the primary layer has a thickness in a range of 5 to 50 microns; and
an amount of nuclear fuel loaded into the cavity of the base layer of the strengthened cladding, wherein the nuclear fuel is comprised of an Uranium containing compound, wherein the Uranium containing compound is enriched to a 235U level of about 5% or less, and wherein the amount of nuclear fuel can support an 18 month fuel cycle at a burnup of about 68 Megawatt-days/kilogram-Uranium or more.

2. The fuel rod as claimed in claim 1, wherein the Chromium alloy of the primary layer comprises Yttrium, Molybdenum, Iron, Aluminum, Nitrogen, or a combination thereof.

3. The fuel rod as claimed in claim 1, wherein the base layer has the wall thickness in the range of 0.2 millimeters to 0.5 millimeters.

4. The fuel rod as claimed in claim 1, wherein the coating comprises an interlayer, wherein the interlayer is positioned between the base layer and the primary layer, and wherein the interlayer is configured to increase a formation temperature of a eutectic between the base layer and the primary layer.

5. The fuel rod as claimed in claim 4, wherein the interlayer comprises Molybdenum, Tantalum, or Niobium.

6. The fuel rod claimed in claim 4, wherein the interlayer has a thickness in a range of 10 microns or less.

7. The fuel rod as claimed in claim 1, wherein the coating comprises a top layer surrounding the primary layer, wherein the top layer comprises a Chromium alloy or a ceramic material.

8. The fuel rod as claimed in claim 7, wherein the top layer comprises a Chromium alloy, and wherein the Chromium alloy comprises Yttrium or Molybdenum.

9. The fuel rod as claimed in claim 7, wherein the top layer comprises a Chromium alloy, and wherein the Chromium alloy comprises Iron and Aluminum.

10. The fuel rod s claimed in claim 7, wherein the top layer comprises a ceramic material, and wherein the ceramic material comprises Chromium, Nitrogen, Niobium, or any combination thereof.

11. The fuel rod as claimed in claim 7, wherein the top layer has a thickness of 10 microns or less.

12. The fuel rod as claimed in claim 1, wherein the base layer has a wall thickness of less than 0.575 millimeters.

13. The fuel rod as claimed in claim 12, wherein the base layer has a wall thickness of 0.5 millimeters or less.

14. A method for producing a fuel rod for a nuclear reactor, the method comprising:
producing a base layer for a cladding of the fuel rod, wherein the base layer is comprised of a Zirconium alloy, wherein the base layer has a wall thickness of less than 1 millimeter and wherein the base layer defines a cavity therein;
applying a coating onto the base layer to produce the cladding, the coating comprising a primary layer, wherein the primary layer is comprised of Chromium or a Chromium alloy, wherein the primary layer has a thickness in a range of 5 to 50 microns; and
loading the cladding with an amount of Uranium based fuel, wherein the Uranium based fuel is enriched to a level of 4.95% or less, and wherein the amount of Uranium based fuel can support an 18-month fuel cycle at a burnup of about 68 Megawatt-days/kilogram-Uranium or more.

15. The method as claimed in claim 14, wherein the primary layer of the coating is applied with a cold spray, a thermal spray, or a Physical Vapor Deposition process.

16. The method as claimed in claim 14, wherein the coating comprises an interlayer configured to increase a formation temperature of a eutectic between the base layer and the primary layer, wherein the interlayer is applied with a thermal spray process or a Physical Vapor Deposition process before applying the primary layer.

17. The method as claimed in claim 16, wherein the interlayer comprises Molybdenum, Tantalum, or Niobium.

18. The method as claimed in claim 14, wherein the coating comprises a top layer comprised of a Chromium alloy or a ceramic material, wherein the top layer is applied with a thermal spray process or a Physical Vapor Deposition process after applying the primary layer, and wherein the top layer has a thickness of 10 microns or less.

19. The method as claimed in claim 18, wherein the top layer comprises a Chromium alloy, and wherein the Chromium alloy comprises Yttrium or Molybdenum.

20. The method as claimed in claim 14, wherein the Chromium alloy of the primary layer comprises Yttrium, Molybdenum, Iron, Aluminum, Nitrogen, or a combination thereof.
